(19) United States
(12) Patent Application Publication
(10) Pub. No.: US 2003/0062193 A1
(43) Pub. Date: Apr. 3, 2003

(54) Flexible structure with integrated sensor/actuator

(76) Inventors: Jacob Thaysen, Copenhagen (DK); Ole Hansen, Horsholm (DK); Aric Menon, Hellerup (DK); Anja Boison, Valby (DK)

Correspondence Address: BIRCH STEWART KOLASCH & BIRCH, PO BOX 747, FALLS CHURCH, VA, 22040-0747, US

(21) Appl. No.: 10/006,582

(22) Filed: Dec. 10, 2001

Related U.S. Application Data
(60) Provisional application No. 60/317,488, filed on Sep. 7, 2001.

(51) Int. Cl. H05K 1/03

(52) U.S. Cl. 174/255

(57) ABSTRACT

A polymer-based flexible structure with integrated sensing/actuator means is presented. Conventionally, silicon has been used as a piezo-resistive material due to its high gauge factor and thereby high sensitivity to strain changes in a sensor. By using the fact that e.g. an SU-8 polymer is much softer than silicon and that e.g. a gold resistor is easily incorporated in SU-8 polymer structure it has been demonstrated that a SU-8 based cantilever sensor is almost as sensitive to stress changes as the silicon piezo-resistive cantilever.

### FIELD OF THE INVENTION

The present invention relates to a flexible structure comprising an integrated sensing/actuating element or elements. The integrated sensing/actuating elements are electrically accessible and at least partly encapsulated in a flexible and electrically insulating body so that the flexible structure may be operable in e.g. an electrically conducting environment.

### BACKGROUND OF THE INVENTION

The use of e.g. the SU-8 polymer within the MEMS field has been exponentially growing during the last couple of years. The fact that SU-8 is very chemically resistant makes it possible for the use as a component material. Due to its ability of defining layers with thickness' between 1 μm and 1 mm with high aspect ratio (>20), SU-8 has been a popular and cheap alternative to silicon for the fabrication of passive components. Such components include micro-channels, micro-molds for electroplating or masters for hot embossing. Passive SU-8 based atomic force microscopy (AFM) cantilevers have also been demonstrated.

WO 00/66266 discloses silicon-based micro-cantilever, micro-bridge or micro-membrane type sensors having piezo-resistive readout so as to form an integrated readout mechanism. Such micro-cantilevers, micro-bridges or micro-membranes sensors are suitable for use in micro-liquid handling systems so as to provide an integrated detection scheme for monitoring physical, chemical and biological properties of liquids handled in such systems

Since silicon exhibits very good mechanical behaviors and also a very high piezo-resistive coefficient, SU-8 has so far not been considered as an alternative as a sensor material with integrated readout.

However, in case silicon-based sensors with integrated readout are to be operated in a conducting liquid environment, encapsulation of the electronic circuit making up the integrated readout is required—otherwise, the electronic circuit may short-circuit causing the integrated readout to fail to operate.

Furthermore, the fabrication of silicon-based sensor are rather complicated due to the comprehensive process sequence required in order to fabricate such sensors. A consequence of the comprehensive process sequence is directly reflected in the costs causing the fabrication of silicon-based sensors to be very expensive.

It is an object of the present invention to provide a solution to the above-mentioned problems of silicon-based sensor system. Thus, it is an object of the present invention to provide a sensor/actuator with integrated read-out/transducer, which is cheaper, and easier to fabricate compared to silicon sensors.

It is a further object of the present invention to provide a sensor/actuator configuration including an electrically insulating body so that the sensor/actuator may be immersed directly into a liquid environment without the use of a separate encapsulation layer.

### SUMMARY OF THE INVENTION

The above-mentioned objects are complied with by providing, in a first aspect, a flexible structure comprising integrated sensing means, said integrated sensing means being electrically accessible and being at least partly encapsulated in a flexible and electrically insulating body, said integrated sensing means being adapted to sense deformations of the flexible structure.

The flexible structure may be a micro-cantilever having a rectangular form. Typical dimensions of such micro-cantilever may be: width: 50-150 μm, length: approximately 200 μm, and thickness 1-10 μm. Alternatively, the flexible structure may be a micro-bridge having its ends attached to the walls of e.g. an interaction chamber in an liquid handling system. The dimensions (wide, length and thickness) of a micro-bridge may be similar to the dimensions of the micro-cantilever. Alternatively, the flexible structure may be a membrane-like structure forming part of e.g. the sidewalls of an interaction chamber. The flexible structure may also be a stress sensitive membrane—example for use in pressure sensors.

The flexible and electrically insulating body may be a polymer-based body. A first and a second polymer layer may form this flexible polymer-based body where the integrated sensing means is positioned between the first and the second polymer layer.

The integrated sensing means (sensing element or elements) may be a resistor formed by a conducting layer—for example a metal layer such as a gold layer. Alternatively, the conducting layer may comprise a semiconductor material, such as silicon. In case of silicon, the resistor will be a so-called piezo-resistor, which may be integrated, in the polymer-based body using sputtering.

An SU-8 polymer may form the flexible polymer-based body. In case the polymer-based body is formed by two layers of polymer these layers may both be SU-8 polymers.

The flexible structure may further comprise a substantially rigid portion comprising an integrated electrical conductor being at least partly encapsulated in a substantially rigid and electrically insulating body, said integrated electrical conductor being connected to the integrated sensing means and being electrically accessible via a contact terminal on an exterior surface of the substantially rigid body.

The substantially rigid portion may be that part of a micro-cantilever, which is supported by a substrate. As well as the flexible structure, the substantially rigid body may be formed by a first and a second polymer layer. The integrated electrical conductor may be positioned between the first and the second polymer layer. These polymer layers may be SU-8 polymer layers.

The integrated electrical conductor may be formed by a metal layer—for example a gold layer. Alternatively, the integrated electrical conductor may comprise a semiconductor material—for example sputtered silicon.

In a second aspect, the present invention relates to a chip comprising one or more flexible structures according to the first aspect, said chip further comprising additional resistors on a substrate.

In one embodiment, the chip comprises two flexible structures—each of these structures having a resistor. This chip will further comprise two resistors positioned on the substrate. These four resistors are so connected that they form Wheatstone Bridge in combination.

The substrate may be an SU-8 polymer substrate, or, alternative, the substrate may be e.g. a semiconductor material, a metal, glass, or plastic substrate. A suitable semiconductor material is silicon.

In a third aspect, the present invention relates to a sensor comprising a chip according to second aspect. Such sensor could be a micro-cantilever, micro-bridge or micro-membrane type sensor having integrated readout. A closed micro-liquid handling system allows laminated flows of different liquids to flow in the channel without mixing, which opens up for new type of experiments and which reduces noise related to the liquid movement. Neighbouring or very closely spaced micro-cantilevers, micro-bridges or micro-membranes can be exposed to different chemical environments at the same time by:

Laminating the fluid flow vertically in the micro-channel into two or more streams, so that micro-cantilevers or micro-membranes on opposing sides of the micro-channel are immersed in different fluids, or so that a micro-cantilever, micro-bridge, or micro-membrane is exposed to two different fluids.

Laminating the fluid flow horizontally in the micro-channel, so that micro-cantilevers or micro-bridges recessed to different levels in the micro-channel or micro-membranes placed at the top and at the bottom of the channel are exposed to different fluids.

In this way, changes in viscous drag, surface stress, temperature, or resonance properties of adjacent or closely spaced micro-cantilevers, micro-bridges or micro-membranes induced by their different fluid environments, can be compared.

Neighbouring or very closely spaced micro-cantilevers, micro-bridges or micro-membranes can be coated with different chemical or biological substances for immersing adjacent or neighbouring micro-cantilevers, micro-bridges or micro-membranes in different fluids.

In micro-cantilever, micro-bridge or micro-membrane based sensors, the liquid volume may be minimised in order to reduce the use of chemicals and in order to obtain a system which is easy to stabilise thermally.

In a fourth aspect, the present invention relates to an actuator comprising a flexible structure comprising integrated actuator means, said integrated actuator means being electrically accessible and being at least partly encapsulated in a flexible and electrically insulating body, said integrated actuator means being adapted to induce deformations of the flexible structure.

The integrated actuator means (actuator element or elements) may comprise a metal layer. The flexible and electrically insulating body may be a polymer-based body formed by for example an SU-8 polymer. For example, the metal layer may be used as a heater element. Using the fact that the metal and the polymer has different thermal expansion, actuation may be accomplished via the bimorph effect.

In a fifth aspect, the present invention relates to a chip processing method comprising

providing a first insulating layer and patterning this first insulating layer so as to form an upper part of a cantilever,

providing a first conducting layer and patterning this first conducting layer so as to form at least one conductor on a first area of the patterned first insulator,

providing a second conducting layer and patterning this second conducting layer so as to form at least one resistor on a second area of the patterned first insulator, and

providing a second insulating layer so as to at least partly encapsulate the patterned first and second conducting layers, and patterning this second insulating layer so as to form a lower part of a cantilever.

The insulating layers may be polymer layers—for example SU-8 polymer layers. The conducting layers may be metal layers—for example gold layers.

The method may further comprise the step of providing a relatively thicker layer on the second insulating layer and patterning the relatively thicker layer so as to form a substrate. This relatively thicker layer may be a polymer layer or a silicon layer. In case of a polymer layer this layer may be an SU-8 polymer layer.

The method according to the fifth aspect may further comprise the steps of

providing a sacrificial layer on a silicon wafer, wherein the first insulating layer is provided on the sacrificial layer, and

removing the silicon wafer after the providing and the patterning of the relatively thicker layer.

### BRIEF DESCRIPTION OF THE DRAWINGS

The present invention with now be explained in further details with reference to the accompanying figures, where

FIG. 1 shows a process sequence for the fabrication of a polymer-based cantilever—here a SU-8 polymer body,

FIG. 2 shows an example of a complete chip design,

FIG. 3 shows optical images of cantilevers with integrated meander-type resistor, and

FIG. 4 shows the relative change in resistance as a function of the cantilever deflection.

### DETAILED DESCRIPTION OF THE INVENTION

As previously mentioned, the flexible structure may be the movable part of a cantilever beam, the movable part of a micro-bridge, or the movable part of a diaphragm. A detailed description of the present invention will now be provided with reference to a polymer-based cantilever-like structure. This exemplification should, however, not be regarded as a limitation of the present invention to polymer-based cantilever-like structures.

In order to illustrate the sensitivity of an SU-8-based piezo-resistive cantilever, it is compared to the sensitivity of a conventional piezo-resistive silicon cantilever. In this example the surfaces stress sensitivity is compared for the two different sensors.

When molecules bind to a surface of a cantilever, the surface stress Γₛ changes due to molecular interactions. This stress change can then be detected by the integrated piezo-resistor. A simple expression for the sensitivity can be obtained by assuming that the cantilever consists of only one material and an infinitely thin resistor placed on top of the cantilever. The relative change in resistance can be written as:

$$\frac{Δ R}{R} / {σ}_{S} = - K \cdot \frac{4}{h \cdot E}$$

where K is the gauge factor, E is Young's modulus and h is the thickness of the cantilever.

Preferably, a thin gold film is used as the piezo-resistor. Gold has a low gauge factor (K_{Au}=2) compared to silicon (K_{Si}=140) and is therefore considered inferior to silicon as a piezo-resistive sensor material.

From the equation it is seen that the K/E actually determines the stress sensitivity of the cantilever for the same thickness. Since SU-8 has a Young's modulus of 5 GPa and silicon has a Young's modulus of 180 GPa, the ratios becomes (K/E)_{Si}=0.8 GPa⁻¹ and (K/E)_{Su-8/Au}=0.4 GPa⁻¹, which is only a factor of 2 in sensitivity in favor of silicon. The sensitivity of an SU-8 based piezo-resistive cantilever can be further enhanced by integrating a piezo-resistor material with even higher gauge factor. For example, it is possible to integrate a sputtered silicon piezo-resistor with a gauge factor of about 20. In order to use Youngs's modulus for SU-8 in the K/E relation, the stiffness of the piezo-resistor should be neglectable compared to the SU-8 cantilever. This can be achieved by reducing the thickness of the poly-silicon resistor which increases the noise significantly and thereby reducing the signal to noise ratio.

Preferably, an SU-8 based cantilever with integrated piezo-resistive readout is fabricated on a silicon substrate. The substrate is only used in order to be able to handle the chips during processing.

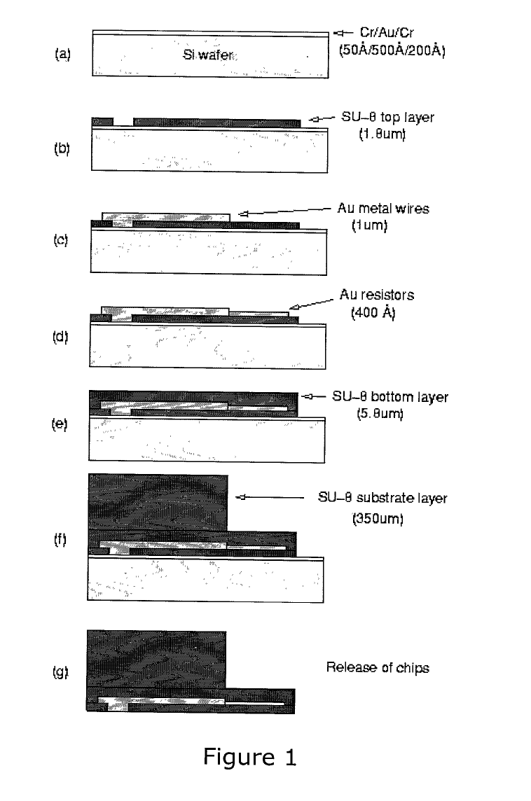

First, a Cr/Au/Cr layer is deposited on the silicon wafer as shown in FIG. 1a. This Cr/Au/Cr layer is used as a very fast etching sacrificial layer. A first layer of SU-8 is then provided, preferably by spinning, on the wafer and patterned as an upper cantilever layer—see FIG. 1b. The thickness of this layer is typically in the range of a few microns—for example in the range 1-5 μm. In FIG. 1b, the thickness of the first layer is 1, 8 μm.

A gold layer with a thickness of approximately 1 μm is then deposited on top of the patterned thin SU-8 layer. A conductor is transferred to the SU-8 layer by standard photoresist/photolithography. This conductor is defined by etching—see FIG. 1c.

In FIG. 1d, another gold layer with a thickness of approximately 400 Å is deposited and a resistor is defined following the same procedure as described in connection with FIG. 1c.

The conductor and the resistor are encapsulated in SU-8 by depositing and patterning of a second SU-8 layer. This second polymer layer forms the lower part of the cantilever—see FIG. 1e. Preferably, the thickness of this second layer is within the range 3-10 μm. In FIG. 1e, the thickness of the second layer is 5, 8 μm.

Finally, an SU-8 polymer layer (approximately 350 μm thick) is spun on the second SU-8 layer and patterned as the chip substrate (FIG. 1f). The chip is finally released by etching of the sacrificial layer—see FIG. 1g.

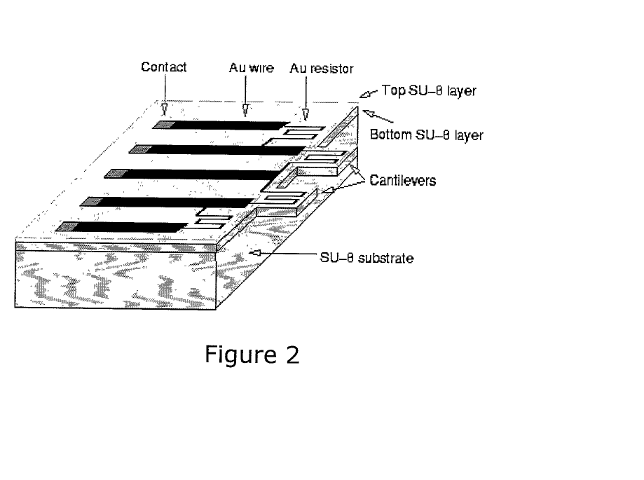

FIG. 2 shows an SU-8 based cantilever chip design comprising two SU-8 cantilevers. As seen, the chip consists of two cantilevers with integrated gold resistors and two gold resistors on the substrate. The four resistors are connected via gold wires in such a way that they in combination form a Wheatstone bridge. The nodes of the Wheatstone bridge are accessible via the shown contact pads.

The advantage of the design shown in FIG. 2 is that one of the cantilevers may be used as a measurement cantilever, while the other cantilever may be used as a common-mode rejection filter. Typical parameters of the cantilevers shown in FIG. 2 are as follows:

TABLE 1
Typical design parameter:

| Parameter | Value | Unit |
|---|---|---|
| Cantilever length | 200 | μm |
| Cantilever width | 100 | μm |
| Cantilever Thickness | 7.3 | μm |
| Spring constant | 7 | N/m |
| Resonant frequency | 49 | kHz |

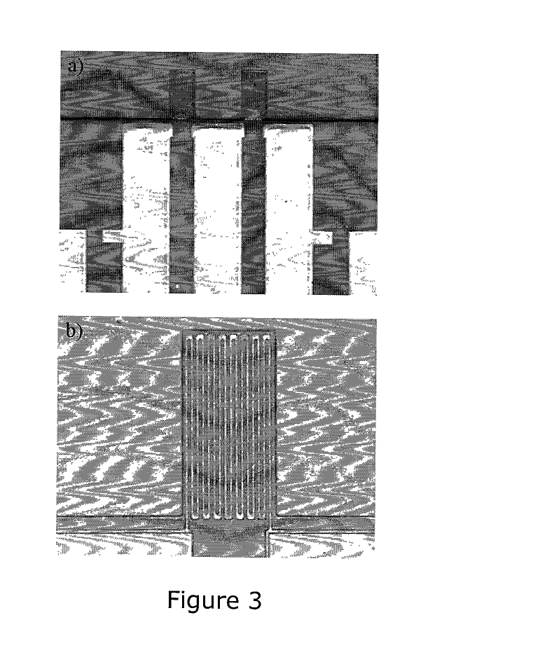

In FIG. 3, optical images of a fabricated chip are shown. In FIG. 3a, both cantilevers are seen. FIG. 3b shows a close-up of one of the cantilevers. The meander-like resistor structure is clearly seen in the image.

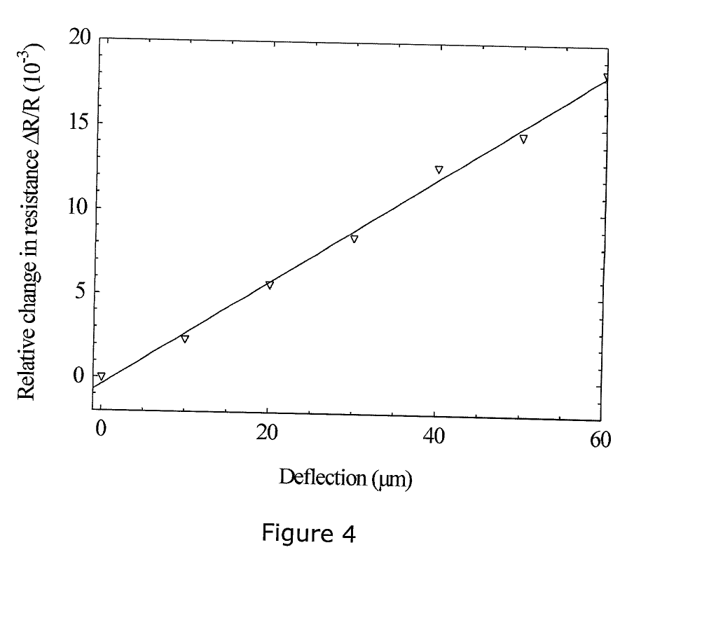

The deflection sensitivity of piezo-resistive SU-8 cantilevers has been measured by observing the relative change in resistance as a function of the cantilever deflection - the result is shown in FIG. 4. It is seen that a straight line can be obtained from the measurement, which indicates that the deformation is purely elastic.

From FIG. 4, the deflection sensitivity can be determined from the slope of the straight line to ΔR/R/Z=0.3 ppm/nm, which yields a gauge factor of K=4. The minimum detectable deflection or minimum detectable surface stress is given by the noise in the system. Since the vibrational noise is considerably lower than the electrical noise sources in the above-mentioned resistor setup, only the Johnson noise and the 1/f noise may be considered. The noise has been measured as a function of frequency for different input voltages. It was observed that the 1/f noise was very low with a knee frequency of about 10 Hz for a Wheatstone bridge supply voltage of 4.5 V.

Table 2: Performance of the SU-8 based piezo-resistive cantilever compared to a piezo-resistive silicon cantilever.

| | SU-8 | Si cantilever |
|---|---|---|
| Parameter | cantilever | (optimized) |
| Deflection sensitivity [nm]⁻¹ | 0.3 · 10⁻⁶ | 4.8 · 10⁻⁶ |
| Minimum detectable deflection [Å] | 4 | 0.4 |
| Surface stress sensitivity [N/m]⁻¹ | 3 · 10⁻⁴ | 1 · 10⁻³ |
| Minimum detectable surface stress | 1 · 10⁻⁴ | 2 · 10⁻⁵ |
| [N/m] | | |

From the above measurements it is possible to summarize the performance of the SU-8 based piezo-resistive cantilever—table 2.

With respect to deflection sensitivity, minimum detectable deflection, surface stress sensitivity and minimum detectable surface stress, the performance is compared to an optimized silicon piezo-resistive cantilever.

It is seen from table 2, that the minimum detectable deflection is 10 times better for the silicon cantilever, but only 5 times better regarding the minimum detectable surface stress. Thus, the SU-8 based piezo-resistive cantilever may e.g. be used as a surface stress bio-chemical sensor, since the change in surface stress due to molecular interactions on a cantilever surface is normally in the order of 10⁻³−1 N/m.

Reducing the thickness of the cantilever can increase the surface stress performance even further. As seen from the previously show equation, the sensitivity is inversely proportional with the thickness. With the given technology it is possible to decrease the cantilever thickness a factor of 2 and thereby decrease the minimum detectable surface stress with a factor of 2.

While the present invention has been described with reference to a particular embodiment, those skilled in the art will recognise that many changes may be made thereto without departing from the spirit and scope of the present invention.

For example, the principle of encapsulating a thin gold resistor into a compliant SU-8 structure can also be used for different kind of sensors, such as stress sensitive micro-bridges or stress sensitive membranes for example used as pressure sensors.

Furthermore, actuation of a compliant SU-8 structure can be realised by depositing on or encapsulating a thin gold film into the SU-8 structure. For example, a gold resistor can be used as a heat element. Using the fact that the gold and the SU-8 have different thermal expansion, the compliant SU-8 structure may be actuated due to the bimorph effect.

By integrating two gold films into the same compliant SU-8 structure, such that the two gold films form a plate capacitor, both a sensor and an actuator based on the electrostatic (capacitive) principle can be obtained.

The compliant structure can also be bonded, glued or welled on pre-defined structures or substrates other than SU-8. For example, plastic, silicon, glass, or metals can be applied. Similarly, other realisations of sensors and actuators can involve the use of other polymers than SU-8 and other metals than gold.

Each of these embodiments and obvious variations thereof is contemplated as falling within the spirit and scope of the claimed invention, which is set forth in the following claims.

1. A flexible structure comprising integrated sensing means, said integrated sensing means being electrically accessible and being at least partly encapsulated in a flexible and electrically insulating body, said integrated sensing means being adapted to sense deformations of the flexible structure.

2. A flexible structure according to claim 1, wherein the flexible and electrically insulating body is a polymer-based body.

3. A flexible structure according to claim 2, wherein the flexible polymer-based body is formed by a first and a second polymer layer.

4. A flexible structure according to claim 3, wherein the integrated sensing means is positioned between the first and the second polymer layer.

5. A flexible structure according to claim 1, wherein the integrated sensing means forms a resistor.

6. A flexible structure according to claim 2, wherein the flexible polymer-based body is formed by an SU-8 polymer.

7. A flexible structure according to claim 3 , wherein the polymer layers are SU-8 polymers.

8. A flexible structure according to claim 5, wherein the resistor is formed by a conducting layer.

9. A flexible structure according to claim 8, wherein the conducting layer is a metal layer.

10. A flexible structure according to claim 9, wherein the metal layer is a gold layer.

11. A flexible structure according to claim 8, wherein the conducting layer comprises a semiconductor material.

12. A flexible structure according to claim 11, wherein the semiconductor material is silicon.

13. A flexible structure according to claim 1, further comprising a substantially rigid portion comprising an integrated electrical conductor being at least partly encapsulated in a substantially rigid and electrically insulating body, said integrated electrical conductor being connected to the integrated sensing means and being electrically accessible via a contact terminal on an exterior surface of the substantially rigid body.

14. A flexible structure according to claim 13, wherein the substantially rigid body is formed by a first and a second polymer layer, and wherein the integrated electrical conductor is positioned between the first and the second polymer layer.

15. A flexible structure according to claim 14, wherein the polymer layers forming the substantially rigid body are SU-8 polymer layers.

16. A flexible structure according to claim 13, wherein the integrated electrical conductor is formed by a metal layer.

17. A flexible structure according to claim 16, wherein the metal layer is a gold layer.

18. A flexible structure according to claim 13, wherein the integrated electrical conductor comprises a semiconductor material.

19. A flexible structure according to claim 18, wherein the semiconductor material is silicon.

20. A chip comprising a flexible structure according to claim 5, said chip further comprising at least three resistors on a substrate.

21. A chip comprising two flexible structures according to claim 5, said chip further comprising two resistors on a substrate.

22. A chip according to claim 21, wherein the substrate is a SU-8 polymer substrate.

23. A chip according to claim 21, wherein the substrate is a silicon substrate.

24. A chip according to claim 21, wherein each of the flexible structures comprises one resistor, and wherein the four resistors are connected to form a Wheatstone Bridge.

25. A sensor comprising a chip according to claim 24.

26. An actuator comprising a flexible structure comprising integrated actuator means, said integrated actuator means being electrically accessible and being at least partly encapsulated in a flexible and electrically insulating body, said integrated actuator means being adapted to induce deformations of the flexible structure.

27. An actuator according to claim 26, wherein the integrated actuator means comprises a metal layer and wherein the flexible and electrically insulating body is a polymer-based body.

28. An actuator according to claim 27, wherein the polymer-based body is formed by an SU-8 polymer.

29. A chip processing method comprising
providing a first insulating layer and patterning this first insulating layer so as to form an upper part of a cantilever,
providing a first conducting layer and patterning this first conducting layer so as to form at least one conductor on a first area of the patterned first insulator,
providing a second conducting layer and patterning this second conducting layer so as to form at least one resistor on a second area of the patterned first insulator, and
providing a second insulating layer so as to at least partly encapsulate the patterned first and second conducting layers, and patterning this second insulating layer so as to form a lower part of a cantilever.

30. A chip processing method according to claim 29, wherein the insulating layers are polymer layers.

31. A chip processing method according to claim 30, wherein the insulating layers are SU-8 polymer layers.

32. A chip processing method according to claim 29, wherein the conducting layers are metal layers.

33. A chip processing method according to claim 32, wherein the metal layers are gold layers.

34. A chip processing method according to claim 29, further comprising the step of providing a relatively thicker layer on the second insulating layer and patterning the relatively thicker layer so as to form a substrate.

35. A chip processing method according to claim 34, wherein the relatively thicker layer is a polymer layer.

36. A chip processing method according to claim 34, wherein the relatively thicker layer is a silicon layer.

37. A chip processing method according to claim 34, further comprising the steps of
providing a sacrificial layer on a silicon wafer, wherein the first insulating layer is provided on the sacrificial layer, and
removing the silicon wafer after the providing and the patterning of the relatively thicker layer.

38. A chip processing method according to claim 35, wherein the relatively thick polymer layer is a SU-8 polymer layer.
